(19) United States
(12) Patent Application Publication
(10) Pub. No.: US 2008/0031720 A1
(43) Pub. Date: Feb. 7, 2008

(54) Apparatus and method for supplying solid raw material to single crystal grower

(75) Inventors: Gyeong-Ho Seo, Gumi-si (KR); In-Kyoo Lee, Gumi-si (KR); Sung-Young Lee, Gumi-si (KR); Hyon-Jong Cho, Gumi-si (KR)

Correspondence Address: GREER, BURNS & CRAIN, LTD., Suite 2500, 300 South Wacker Drive, Chicago, IL, 60606, US

(73) Assignee: SILTRON, INC.

(21) Appl. No.: 11/879,465

(22) Filed: Jul. 17, 2007

(30) Foreign Application Priority Data
Aug. 2, 2006 (KR) 10-2006-0073023

(51) Int. Cl. C30B 35/00; F27D 3/00

(52) U.S. Cl. 414/804; 117/200

(57) ABSTRACT

The present invention relates to an apparatus and a method for supplying a solid raw material to a grower of silicon or germanium semiconductor single crystal. In the solid raw material supply apparatus including a cylindrical body mounted above a crucible for receiving the solid raw material therein, a bottom cover detachably installed in the lower end of the body and basically formed in the shape of a cone, and a connection means for relatively moving the bottom cover upwards and downwards with regard to the body, the conic bottom cover is made from the same material as a semiconductor to be grown to the single crystal and the solid raw material is charged while the bottom cover is spaced away from the melt in the crucible at a predetermined distance, thereby the bottom cover can be used repetitively, and even though the bottom cover is broken by shocks resulted from the fall of the solid raw material, fragments of the bottom cover do not contaminate the melt. Further, the present invention basically forms the bottom cover in the shape of a cone and variously changes or modifies the detailed shape and structure of the bottom cover, thereby preventing breakage of the bottom cover and uniformly dispersedly charging the solid raw material in the crucible.

### BACKGROUND OF THE INVENTION

1. Field of the Invention

The present invention relates to a solid raw material supply apparatus and a solid raw material supply method, and in particular, to a solid raw material supply apparatus and a solid raw material supply method for charging a solid raw material to a grower of silicon or germanium semiconductor single crystal.

2. Description of the Related Art

The Czochralski method that pulls up a crystal as growing the crystal from a silicon or germanium melt in a crucible is well known as a method for producing a single crystal semiconductor. Generally, in the Czochralski method, a polycrystalline solid raw material is charged in the crucible and melted into a melt by heat, a crystal seed is contacted with the melt and pulled up, and thus a single crystal ingot having a desired radius is grown.

The present invention relates to a solid raw material supply apparatus and a solid raw material supply method for charging a crucible with a solid raw material. Generally, a method for supplying a solid raw material to a crucible is classified into the following three methods according to type of the solid raw material: a first method that directly falls a solid raw material in the shape of a chip from a central upper portion of a crucible, a second method that directly falls or obliquely supplies a solid raw material in the shape of a granule from a central upper portion or an inclined upper portion of a crucible, respectively, and a third method that melts a solid raw material as slowly supplying the solid raw material in the shape of a bar from a central upper portion of a crucible. The above-mentioned methods use apparatuses of different structures according to type of a raw material, and have advatages and disadvantages in their own. Among them, the first method is widely used since a raw material can be easily obtained at a competitive cost and a regenerated (recycled) raw material can be used. The first method and an apparatus incorporating the first method are disclosed in the following prior arts.

For example, JP Laid-open Patent Publication No. 2004-244236 and WO 2002/068732 disclose a solid raw material supply apparatus including a cylindrical body for receiving a solid raw material in the shape of a chip to be supplied to a crucible, a top cover for closing an upper opening of the body, a bottom cover for closing a lower opening of the body, and a support bar or wire connected to an upper end of the bottom cover through the body and configured to prevent the fall of the bottom cover due to load of the solid raw material and properly open the bottom cover to control the falling amount and rate of the solid raw material. Typically, the body, the top and bottom covers and the support bar are made from quartz or quartz glass, and the support wire is made from a heat-resistant metal. The bottom cover is formed in the shape of a cone, of which an apex faces the solid raw material. The bottom cover closes the lower opening of the body by the support bar or the support wire. As the support bar or the support wire moves downwards, the bottom cover opens the lower opening of the body so that the solid raw material is charged in the crucible.

However, when the solid raw material loaded in the body is charged in the crucible, the solid raw material runs against the surface of the bottom cover, and in some instances, the bottom cover made from quartz or quartz glass is broken due to shocks caused by the fall of the solid raw material. As a result, fragments of the bottom cover fall in the crucible with the solid raw material and a quartz composition contaminates a high purity melt, thereby resulting in a poor quality single crystal ingot and low yield of a high quality single crystal ingot.

Meanwhile, the solid raw material supply apparatus is used in additionally charging or recharging a crucible with a solid raw material as well as in initially charging a vacant crucible with the solid raw material. Productivity of a single crystal ingot is proportional to the volume of the crucible and the amount of the melt charged in the crucible. If the solid raw material is initially charged in a vacant crucible and is melted, the volume of the melt is significantly reduced in comparison to the volume of the solid raw material due to disappearance of vacant spaces among particles of the solid raw material. Thus, the solid raw material is additionally charged to increase the amount of the melt and the productivity of a single crystal ingot. Further, in a conventional single crystal growth method, a grower is cooled after an ingot is grown, and the grown ingot is drawn from the grower. At this time, a melt remaining in the crucible is expanded during solidification, and thus the crucible made from quartz is broken or cracked, thereby resulting in a waste of the crucible and the melt. In order to overcome the problem, a solution is suggested that additionally charges the solid raw material in the melt remaining in the crucible without cooling the grower, thereby allowing for several times of single crystal ingot growth using the same crucible.

An additional charge or recharge has points to be considered in comparison with an initial charge. For example, because the additional charge or recharge is performed on a melt remaining in a crucible, the melt may splash by the falling solid raw material and thus splash of the melt may be attached to a semiconductor single crystal grower or a solid raw material supply apparatus. In worse instances, the melt may scatter, which may make a single crystal growth impossible. Therefore, a falling rate of the solid raw material should be properly reduced, and the solid raw material should be uniformly dispersedly fallen in the crucible.

In order to achieve the aims, the above WO 2002/068732 suggests a solid raw material supply apparatus in which a cylindrical body is formed larger in the downward direction or the size and vertical angle of a conic bottom cover are controlled. However, the prior art did not achieve satisfactory results. Further, the prior art has proposed to reduce a falling rate of a solid raw material or fall the solid raw material discontinuously, but the solid raw material stays longer in a grower heated with high temperature. As a result, the solid raw material loaded in the cylindrical body of the solid raw material supply apparatus is partially melted or expanded, thereby resulting in poor falling of the solid raw material. Moreover, the prior art has studied to solve the scattering problem of the melt by falling the solid raw material after solidification of the surface of the melt. However, it requires additional apparatus and time to solidify the surface of the melt, thereby resulting in reduced productivity and contamination of the melt caused by separation of a portion of the quartz crucible.

In order to solve the above problems, i.e. scattering of a melt caused by the fall of a solid raw material or separation of a portion of a quartz crucible during charge after solidification of the surface of the melt, U.S. Pat. No. 6,908,509 discloses that a bottom cover is made from a single crystal or polycrystalline silicon meltable to a silicon melt, and that when a solid raw material is loaded in a body of a solid raw material supply apparatus, the body is dipped in the melt and the bottom cover is melted so that the solid raw material in the body is supplied to the melt. However, because the bottom cover of the supply apparatus is melted away, this prior art has a drawback of displacing with a new disposable bottom cover every time.

### SUMMARY OF THE INVENTION

The present invention is designed to solve the problems of the prior arts, and therefore it is an object of the present invention to provide a solid raw material supply apparatus having such a structure that prevents scattering or contamination of a melt occurring when the solid raw material is supplied to a semiconductor single crystal grower.

It is another object of the present invention to provide a solid raw material supply method that prevents scattering or contamination of a melt occurring when the solid raw material is supplied to a semiconductor single crystal grower.

After repeated research and experiments in order to achieve the objects, the inventors have found that material and type of a bottom cover may be controlled to prevent scattering or contamination of a melt and achieve an optimum charging efficiency, and completed the present invention.

According to the solid raw material supply method of the present invention, a conic bottom cover is made from the same material as a semiconductor to be grown to a single crystal and the solid raw material is charged in a crucible such that the bottom cover is not dipped in a melt in the crucible but is spaced from the melt. Thereby the solid raw material supply method allows for a repetitive use of the bottom cover, and even though the bottom cover is broken due to shocks caused by the fall of the solid raw material, the method prevents the broken fragments of the bottom cover from contaminating the melt.

Specifically, the solid raw material supply method according to an exemplary embodiment of the present invention as a method for supplying a solid raw material, being a raw material of a semiconductor single crystal, to a crucible containing a melt for a semiconductor single crystal growth at a predetermined height, comprises the steps of loading the solid raw material in a cylindrical body of a solid raw material supply apparatus while a conic bottom cover closes an opening of the body such that an apex of the conic bottom cover is located in an inner space of the body, mounting the cylindrical body of the solid raw material supply apparatus above the crucible such that the bottom cover faces a melt in the crucible, and relatively moving the body and the bottom cover with the bottom cover being spaced away from the melt in the crucible at a predetermined distance to open the opening of the body, thereby charging the crucible with the solid raw material, wherein the bottom cover is made from a single crystal or polycrystalline semiconductor of the same material as the semiconductor.

Preferably, the step of charging the crucible with the solid raw material includes relatively rotating the crucible and the body of the supply apparatus at a speed of 0.1 to 3 rpm so that the solid raw material is uniformly dispersed and charged in the crucible.

Preferably, the solid raw material is a polycrystalline semiconductor in the shape of a granule or a chip having a particle diameter of 3 to 30 mm, thereby reducing falling shocks applied to the bottom cover and preventing the scattering of the melt.

Meanwhile, a solid raw material supply apparatus of the present invention has a bottom cover whose the basic shape is a cone and its details and structure are variously changed so that breakage of the bottom cover is prevented and the solid raw material is uniformly dispersedly charged in the crucible to prevent the scattering of the melt.

Specifically, the solid raw material apparatus according to the exemplary embodiments of the present invention, as an apparatus for supplying a solid raw material, being a raw material of a semiconductor single crystal, to a crucible of a semiconductor single crystal grower, includes a cylindrical body located above the crucible and detachably installed in the grower for receiving the solid raw material therein, a bottom cover detachably installed in the bottom of the body for preventing the fall of the solid raw material and basically formed in the shape of a cone having an apex facing the solid raw material, and a connection means connected in the vicinity of the apex of the conic bottom cover through the middle of an inner space of the body for relatively moving the bottom cover upwards and downwards with regard to the body, wherein a plurality of grooves are formed on a conic surface of the bottom cover facing the solid raw material from the apex of the cone downwards.

Further, according to another exemplary embodiment of the present invention, a vertical cross-section of the bottom cover is formed in the shape of a bell in which the angle relative to a lower surface of the bottom cover becomes greater from the apex of the cone of the bottom cover downwards.

Further, according to another exemplary embodiment of the present invention, a vertical cross-section of the bottom cover is formed in the shape of an ingot shoulder in which the angle relative to a lower surface of the bottom cover becomes smaller from the apex of the cone of the bottom cover to a point downwards and becomes greater from the point downwards.

Further, according to another exemplary embodiment of the present invention, at least one concave portion or convex portion is formed on a conic surface of the bottom cover facing the solid raw material.

Here, the bottom cover is preferably made from the same material as a semiconductor to be grown to a crystal, such as silicon or germanium. Because the bottom cover has such structure and shape that reduces falling shocks of the solid raw material, the bottom cover may be made from a quartz glass.

### BRIEF DESCRIPTION OF THE DRAWINGS

Other objects and aspects of the present invention will become apparent from the following description of embodiments with reference to the accompanying drawing in which:

FIG. 1 is a cross-sectional view of a solid raw material supply apparatus in accordance with an exemplary embodiment of the present invention.

FIG. 2 is a cross-sectional view of the solid raw material supply apparatus in which a solid raw material is charged into a crucible in accordance with an exemplary embodiment of the present invention.

FIGS. 3 to 6 are views of various examples of a bottom cover of the solid raw material supply apparatus in accordance with an exemplary embodiment of the present invention.

### DESCRIPTION OF THE PREFERRED EMBODIMENT

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

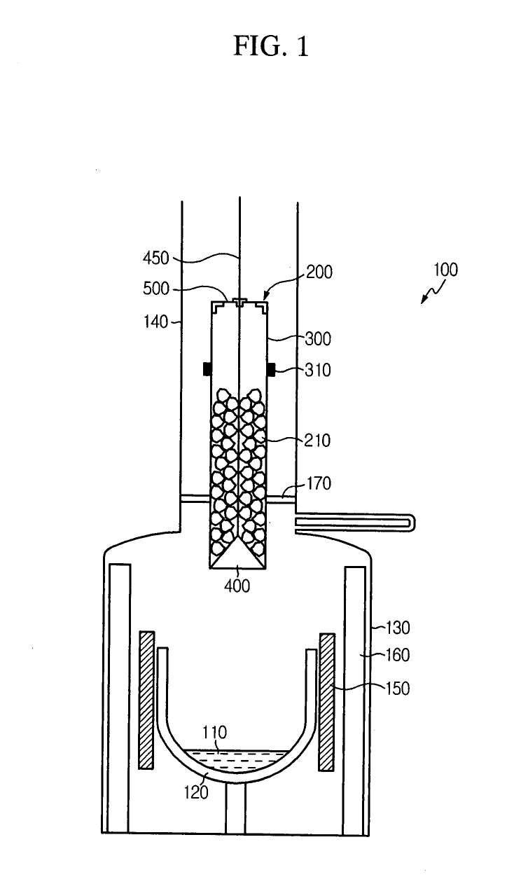

FIG. 1 is a cross-sectional view of a solid raw material supply apparatus in accordance with an exemplary embodiment of the present invention. Although this exemplary embodiment shows a semiconductor to be grown to a crystal is silicon, the present invention may be applied to the case that the other semiconductors such as germanium are grown to a crystal. In addition, although this exemplary embodiment shows a solid raw material is a chip-shaped polycrystalline silicon, the present invention may be applied to the case that a polycrystalline silicon in the shape of a granule or a recycled silicon is supplied. Further, although this exemplary embodiment shows a solid raw material is additionally charged or recharged in a melt remaining in the crucible, the present invention may be applied to the case that the solid raw material is initially charged in a vacant crucible.

As shown in FIG. 1, the solid raw material supply apparatus 200 according to the exemplary embodiment is mounted at a gate 170 of a single crystal grower 100 so that the supply apparatus 200 supplies a polycrystalline silicon raw material 210 formed in the shape of a chip to a crucible 120 of the single crystal grower 100. The solid raw material supply apparatus 200 includes a cylindrical body 300 for receiving the polycrystalline silicon raw material 210 therein, a bottom cover 400 formed in the shape of a cone having an apex for closing a lower opening of the body 300, a top cover 500 for closing an upper opening of the body 300, and a connection means 450 connected in the vicinity of the apex of the bottom cover 400 through an inner space of the body 300.

The body 300 has such a cylindrical structure that the polycrystalline silicon raw material 210 is loaded therein and may be tapered larger downwards for easier fall of the polycrystalline silicon raw material 210. A stopper 310 is formed protruding continuously or discontinuously along the periphery of the body 300. When the solid raw material supply apparatus 200 is mounted at an upper portion of the grower 100, the stopper 310 is stuck in the gate 170 so that the body 300 is fixed at a predetermined position. The body 300 is typically made from a quartz glass that is high temperature-resistant, has a low susceptibility to contamination and is transparent.

The bottom cover 400 formed in the shape of a cone has the lower portion of which diameter is formed larger than a diameter of the lower opening of the body 300. When the bottom cover 400 is mounted such that the apex of the cone of the bottom cover 400 faces the inner space of the body 300, the bottom cover 400 completely closes the lower opening of the body 300. In this exemplary embodiment, the bottom cover 400 is made from a single crystal or polycrystalline silicon having purity and concentration of the same as or substantially equivalent to the polycrystalline silicon raw material 210.

The connection means 450 is connected in the vicinity of the apex of the cone of the bottom cover 400 and connected to a seed connector (not shown) through the inner space of the body 300 and the top cover 500. The connection means 450 serves as a support wire or bar for preventing the fall of the bottom cover 400 due to load of the polycrystalline silicon raw material 210. The connection means 450 is also configured to move the bottom cover 400 downwards so that the lower opening of the body 300 is opened when the crucible 120 is charged with the polycrystalline silicon raw material 210. If the connection means 450 is formed of a support wire, the connection means 450 is made from high melting point metals having contamination resistance and excellent mechanical strength at high temperature, for example molybdenum or tungsten, or an alloy thereof. If the connection means 450 is formed of a support bar, the connection means 450 is made from high melting point metals or an alloy thereof, or a quartz glass equal to material of the body 300.

The top cover 500 is detachably installed at an upper end of the body 300 and is made from a quartz glass for observation, high temperature resistance and contamination prevention.

The grower 100 having the solid raw material supply apparatus 200 includes a lower chamber 130 and an upper chamber 140. The lower chamber 130 and the upper chamber 140 air-tightly seal the grower 100 to block the grower 100 from the external environment. The lower chamber 130 has a crucible 120, a heater 150, and a heat insulating section 160 therein. A driving device (not shown) may be connected to the crucible 120 for moving the crucible 120 upwards and downwards or rotating the crucible 120. The upper chamber 140 is formed in the shape of a cylinder and is installed above the crucible 120 extending from the lower chamber 130. The upper chamber 140 provides a space for installing the solid raw material supply apparatus 200 or pulling up a single crystal ingot.

A method for charging a crucible 120 of a single crystal grower 100 with a polycrystalline silicon raw material 210 using the solid raw material supply apparatus 200 according to the exemplary embodiment of the present invention is described as follows.

First, when a bottom cover 400 closes a lower opening of a body 300 of the solid raw material supply apparatus 200 such that an apex of a cone of the bottom cover 400 faces an inner space of the body 300, the polycrystalline silicon raw material 210 as a solid raw material is loaded in the apparatus 200. Preferably, the polycrystalline silicon raw material 210 is formed in the shape of a chip or a granule and has a particle diameter of 3 to 30 mm. If the diameter is less than 3 mm, the solid raw material 210 may leak through a gap between the body 300 and the bottom cover 400 when the solid raw material supply apparatus 200 containing the solid raw material 210 is transferred or mounted in the grower 100. If the diameter is larger than 30 mm, excessive shocks may be applied to the bottom cover 400 during loading or falling of the solid raw material 210, thereby the bottom cover 400 may be damaged or the melt in the crucible 120 may scatter during charge of the solid raw material 210. Here, the range of the diameter is just a preferable example for the purpose of illustration only, and the range of the diameter may go beyond the illustrated range, if numerical precision of the body 300 and the bottom cover 400 is high or shock-resistant strength resulted from the size of the body 300 and the bottom cover 400 is sufficiently large.

Next, the solid raw material supply apparatus 200 containing the polycrystalline silicon raw material 210 therein is mounted in the single crystal grower 100. Specifically, the bottom cover 400 is connected to the seed connector (not shown) by the connection means 450. The body 300 is moved downwards to an inner space of the lower chamber 130 through the upper chamber 140 and the gate 170. The stopper 310 formed along the periphery of the body 300 is stuck in the gate 170 formed protruding in an inner wall of the upper chamber 140 so that the movement of the body 300 stops at a predetermined position. At this time, the crucible 120 contains the silicon melt 110 melted after an initial charge of the polycrystalline silicon raw material 210 or the silicon melt 110 remaining after single crystal growth.

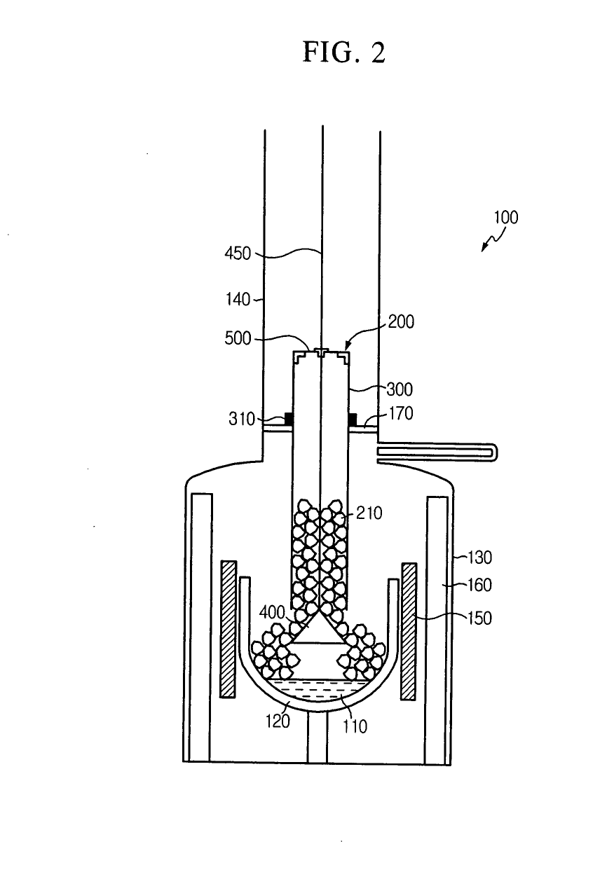

Subsequently, the connection means 450 is lowered downwards so that the bottom cover 400 is moved downwards to open the lower opening of the body 300. As shown in FIG. 2, the polycrystalline silicon raw material 210 loaded in the body 300 falls through a gap between the body 300 and the bottom cover 400, so that the solid raw material is charged in the crucible 120.

At this time, the moving distance of the bottom cover 400 is controlled so the bottom cover 400 is not in a direct contact with the melt 110 in the crucible 120 but is spaced away from the melt 110 at a predetermined distance. The predetermined distance is such that the melt 110 does not scatter by the falling polycrystalline silicon raw material 210 and the surface of the melt 110 risen by charge of the polycrystalline silicon raw material 210 does not come in contact with the bottom cover 400. The predetermined distance may be controlled in consideration of the size, the falling time of the solid raw material 210 and the volume of the crucible 120, and if necessary, may be increased by relatively moving the body 300 and the bottom cover 400 with regard to the crucible 120 continuously or discontinuously during charge of the polycrystalline silicon raw material 210. Here, the relative movement of the body 300 and the bottom cover 400 with regard to the crucible 120 is such that the crucible 120 may be moved downwards by a driving means (not shown) while the body 300 and the bottom cover 400 are fixed, or that the body 300 and the bottom cover 400 may be moved upwards while the crucible 120 is fixed. A relative movement between the body 300 and the bottom cover 400 is similar to the relative movement between the body 300 and the bottom cover 400, and the crucible 120. Although in this exemplary embodiment, the bottom cover 400 is moved downwards by the connection means 450 while the body 300 is fixed by the stopper 310 so that the lower opening of the body 300 is opened, the body 300 may be moved upwards while the bottom cover 400 is fixed so that the lower opening of the body 300 is opened.

Preferably, during charging the crucible 120 with the polycrystalline silicon raw material 210, the crucible 120 is slowly rotated so that the polycrystalline silicon raw material 210 is uniformly dispersed and charged in the crucible 120. The rotation rate of the crucible 120 is controlled in consideration of the particle size, the amount of the polycrystalline silicon raw material 210, the diameters of the body 300 and the bottom cover 400, the volume of the crucible 120 and the horizontal falling distance of the polycrystalline silicon raw material 210. For example, the crucible 120 may be rotated at the rotation rate of 0.1 to 3 rpm during charge of the polycrystalline silicon raw material 210. If the rotation rate of the crucible 120 is less than 0.1 rpm, the rotation rate of the crucible 120 is excessively slow in comparison to the total falling time of the polycrystalline silicon raw material 210, thereby resulting in a trifle dispersion effect of the polycrystalline silicon raw material 210. If the rotation rate of the crucible 120 is more than 3 rpm, the melt 110 may scatter. Although this exemplary embodiment shows the crucible 120 is rotated while the body 300 is fixed, the body 300 may be rotated while the crucible 120 is fixed, which achieves the same effect.

In this manner, the polycrystalline silicon raw material 210 loaded in the body 300 is charged in the crucible 120. The solid raw material supply apparatus 200 including the body 300 is moved upwards to the upper chamber 140 and a seed for growing a single crystal is connected to a seed connector (not shown), thereby beginning with a single crystal silicon growing process.

As described above, according to the exemplary embodiment, because the bottom cover 400 is made from the same silicon composition as the melt 110, even though a portion of the bottom cover 400 is broken by the falling polycrystalline silicon raw material, the likelihood of contamination of the melt 110 is prevented.

Unlike the above-mentioned prior art, U.S. Pat. No. 6,908,509, the bottom cover 400 made from silicon according to the exemplary embodiment does not get in a direct contact with the melt 110, thereby allowing for a repetitive use of the bottom cover 400. Further, the bottom cover 400 according to the exemplary embodiment has a good elasticity in comparison with a conventional bottom cover made from quartz, thereby leading to increased life of the bottom cover 400.

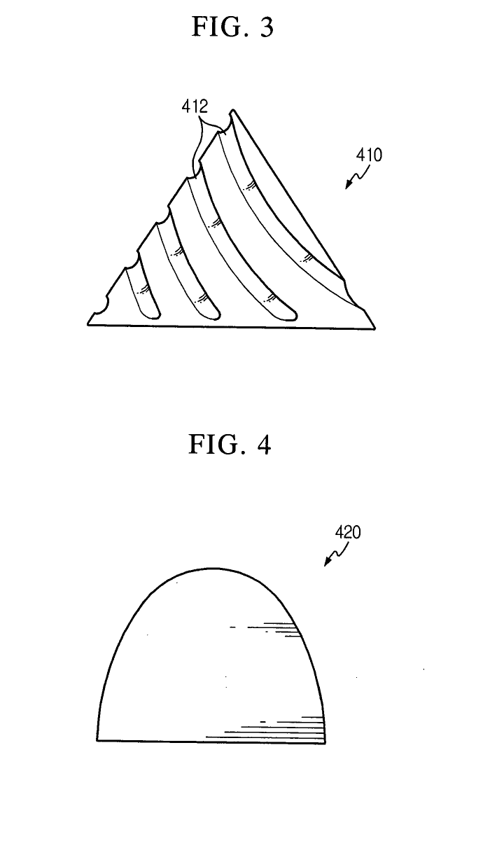

FIGS. 3 to 6 are views of various examples of a bottom cover in accordance with an exemplary embodiment of the present invention.

Referring to FIG. 3, a bottom cover 410 illustrated in a front plan view is basically formed in the shape of a cone. A spiral groove 412 is formed on a conic surface of the bottom cover 410. When the solid raw material is fallen along the conic surface of the bottom cover 410 and charged in the crucible 120, the solid raw material falls along the spiral groove 412 drawing a spiral trace. This has an effect similar to the rotation of the crucible 120. Therefore, in comparison with a bottom cover without a spiral groove, the use of the bottom cover 410 of FIG. 3 disperses better the solid raw material to charge the solid raw material in the crucible 120 more uniformly.

Although this exemplary embodiment shows the groove 412 is formed in the shape of a spiral along the conic surface of the bottom cover 410, the shape of the groove is not limited in this regard. For example, the groove may be linearly formed in the radial direction with regard to an apex of the cone of the bottom cover. In this case, though the falling trace of the solid raw material does not draw a spiral, the horizontal falling distance of the solid raw material passing along the groove is different from the horizontal falling distance of the solid raw material passing along the conic surface without the groove, so that the horizontal dispersion of the solid raw material using the bottom cover with the linear groove is larger than the horizontal dispersion of the solid raw material using a bottom cover without a groove.

The only consideration is that the groove should not be formed to a lower edge of the bottom cover 410, whether the groove is formed spirally or linearly radially. If the groove is formed to the lower edge of the bottom cover, when the lower opening of the body is closed by the bottom cover as shown in FIG. 1, a gap is formed between the bottom cover and the body, through which the solid raw material may leak. Therefore, the groove is preferably formed at least before a point where the bottom cover gets in contact with the body 300.

Meanwhile, the width and depth, cross-sectional shape and number of the groove is not limited to a specific range and may be controlled in consideration of the particle size of the solid raw material and the diameter of the bottom cover. Preferably, taken the effect of the exemplary embodiment described with reference to FIGS. 1 and 2 into consideration, the material of the bottom surface 410 is the same as the solid raw material. However, the bottom cover 410 may be made from conventional materials, for example quartz glass, high melting point metals or an alloy thereof.

As shown in FIG. 4, the shape of a bottom cover 420 illustrated in a front plan view is generally similar to a cone. However, describing more specifically, the bottom cover 420 is formed in the shape of a bell in which the angle relative to a lower surface of the bottom cover 420 becomes larger from an apex downwards. The bottom cover 420 of FIG. 4 is effective in preventing the conventional problem, breakage of the bottom cover. That is to say, in the case of a simply conic bottom cover, a lower edge of the bottom cover is weak to shocks of the falling solid raw material. The bottom cover 420 according to the exemplary embodiment has a larger angle of inclination relative to a lower surface downwards. The solid raw material falls aslant at the lower edge of the bottom cover, thereby reducing shocks applied to the bottom cover. Therefore, the bottom cover 420 according to the exemplary embodiment solves the problems, for example contamination of the melt caused by breakage of the bottom cover and reduced life in comparison with a simply conic bottom cover in the prior art.

As described above, because the bottom cover 420 of FIG. 4 solves the breakage problem, the bottom cover 420 may be made from quartz glass, high melting point metals or an alloy thereof. Alternatively, the bottom cover 420 may be made from the same material as a solid raw material to be charged.

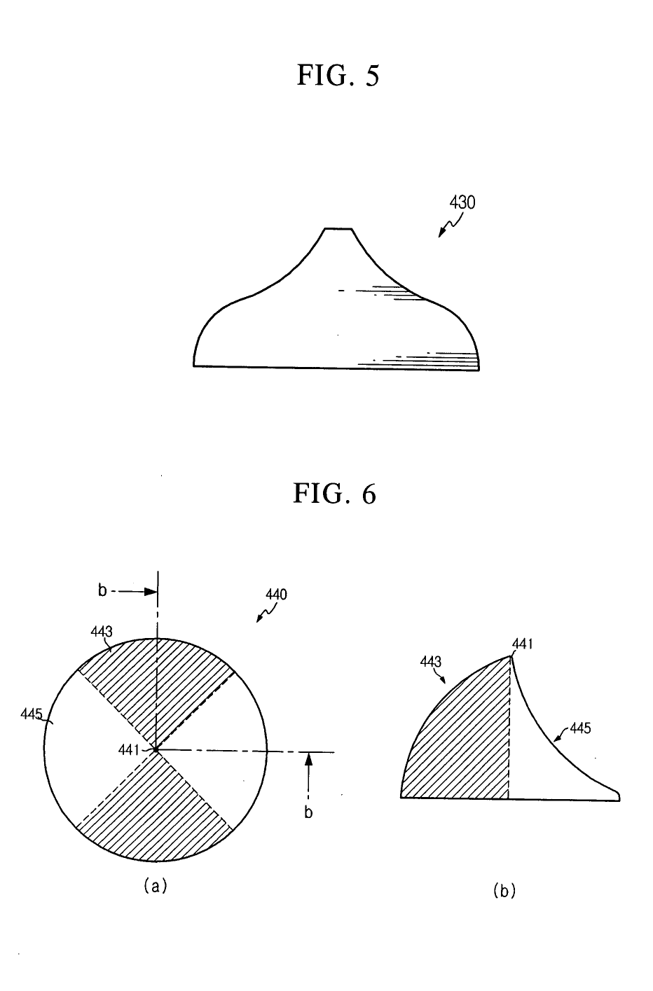

As shown in FIG. 5, a bottom cover 430 illustrated in a front plan view is similar to the bottom cover 420 of FIG. 4 in aspects of shape and effect. More specifically, the bottom cover 430 is formed in the shape of an ingot shoulder in which an angle of inclination relative to the lower surface of the bottom cover becomes smaller from an apex to a point downwards and becomes larger from the point downwards. This allows for easy manufacture of a bottom cover. Manufacture of the bottom covers 410 and 420 of the above exemplary embodiments requires a further process such as casting, whereas the bottom cover 430 of the exemplary embodiment is manufactured using an ingot shoulder portion as it is generally a thrown-away portion of a semiconductor. Thereby the bottom cover 430 eliminates the need for further device or cost for manufacture, is made from the same material as a solid raw material to be charged, and is preferable in the point of view of recycle of a semiconductor material.

FIG. 6(a) is a top plan view of a bottom cover 440, and FIG. 6(b) is a cross-sectional view taken along the line b-b of FIG. 6(a). As shown in FIG. 6, the bottom cover 440 is formed in the shape of a cone in which convex portions 443 and concave portions 445 are formed alternately in the circumferential direction on a conic surface relative to an apex 441. The bottom cover 440 of FIG. 6 allows for dispersedly charge of the solid raw material. The horizontal falling distance of the solid raw material passing along the convex portion 443 is different from that of the solid raw material passing along the concave portion 445, thereby resulting in a larger horizontal dispersion than the horizontal dispersion of a simply conic bottom cover in the prior art.

Although this exemplary embodiment shows two pairs of the convex portions and the concave portions are alternately arranged, the number or arrangement of the convex portion and concave portion is not limited in this regard. For example, convex portions only or concave portions only may be formed on a conic surface of a simply conic bottom cover. In this case, the horizontal falling distance of the solid raw material passing along the convex portion or the concave portion is different from the horizontal falling distance of the solid raw material passing along the conic surface, thereby resulting in a larger horizontal dispersion due to the difference of the falling distance. Alternatively, the convex portion and the concave portion may be irregularly arranged and a crucible and the bottom cover may be relatively rotated thereby to improve the dispersion.

As described above, the bottom cover 440 of FIG. 6 may be made from various materials. Preferably, the bottom cover 440 is made from the same material as a solid raw material to be charged, taken into consideration that the lower edge of the concave portion 445 is weak to shocks of the solid raw material.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### APPLICABILITY TO THE INDUSTRY

As described above, according to the present invention, a conic bottom cover is made from the same material as a semiconductor to be grown to a single crystal, and when a solid raw material is charged in a melt in a crucible, a bottom cover is not dipped in the melt but is spaced away from the melt at a predetermined distance. Therefore, the bottom cover can be used repetitively, and even though the bottom cover is broken by shocks resulted from the fall of the solid raw material, fragments of the bottom cover do not contaminate the melt.

Further, according to the present invention, the bottom cover is basically formed in the shape of a cone, and its details and structure are variously changed or modified, thereby preventing the breakage of the bottom cover and uniformly dispersedly charging the solid raw material in a crucible.

What is claimed is:

1. An apparatus for supplying a solid raw material to a crucible of a semiconductor single crystal grower, the solid raw material being a raw material of a semiconductor single crystal, the apparatus including:
a cylindrical body located above the crucible and detachably installed in the grower for receiving the solid raw material therein;
a bottom cover detachably installed in the bottom of the body for preventing the fall of the solid raw material and basically formed in the shape of a cone having an apex facing the solid raw material; and
a connection means connected in the vicinity of the apex of the conic bottom cover through the middle of an inner space of the body for relatively moving the bottom cover upwards and downwards with regard to the body,
wherein a plurality of grooves are formed on a conic surface of the bottom cover facing the solid raw material from the apex of the cone of the bottom cover downwards.

2. The apparatus of claim 1,
wherein a plurality of the grooves are formed in the shape of a spiral curve, viewed from the top of the bottom cover.

3. The apparatus of claim 1,
wherein the bottom cover is made from a single crystal or polycrystalline semiconductor of the same material as the semiconductor.

4. The apparatus of claim 3,
wherein the semiconductor is silicon or germanium.

5. The apparatus of claim 1,
wherein the body and the bottom cover are made from a quartz glass.

6. The apparatus of claim 1,
wherein the connection means is formed of a support wire or bar made from high melting point metals including molybdenum and tungsten, or an alloy thereof.

7. An apparatus for supplying a solid raw material to a crucible of a semiconductor single crystal grower, the solid raw material being a raw material of a semiconductor single crystal, the apparatus including:
a cylindrical body located above the crucible and detachably installed in the grower for receiving the solid raw material therein;
a bottom cover detachably installed in the bottom of the body for preventing the fall of the solid raw material and basically formed in the shape of a cone having an apex facing the solid raw material; and
a connection means connected in the vicinity of the apex of the conic bottom cover through the middle of an inner space of the body for relatively moving the bottom cover upwards and downwards with regard to the body,
wherein a vertical cross-section of the bottom cover is formed in the shape of a bell in which the angle relative to a lower surface of the bottom cover becomes greater from the apex of the cone of the bottom cover downwards.

8. The apparatus of claim 7,
wherein the bottom cover is made from a single crystal or polycrystalline semiconductor of the same material as the semiconductor.

9. The apparatus of claim 8,
wherein the semiconductor is silicon or germanium.

10. The apparatus of claim 7,
wherein the body and the bottom cover are made from a quartz glass.

11. The apparatus of claim 7,
wherein the connection means is formed of a support wire or bar made from high melting point metals including molybdenum and tungsten, or an alloy thereof.

12. An apparatus for supplying a solid raw material to a crucible of a semiconductor single crystal grower, the solid raw material being a raw material of a semiconductor single crystal, the apparatus including:
a cylindrical body located above the crucible and detachably installed in the grower for receiving the solid raw material therein;
a bottom cover detachably installed in the bottom of the body for preventing the fall of the solid raw material and basically formed in the shape of a cone having an apex facing the solid raw material; and
a connection means connected in the vicinity of the apex of the conic bottom cover through the middle of an inner space of the body for relatively moving the bottom cover upwards and downwards with regard to the body,
wherein a vertical cross-section of the bottom cover is formed in the shape of an ingot shoulder in which the angle relative to a lower surface of the bottom cover becomes smaller from the apex of the cone of the bottom cover to a point downwards and becomes greater from the point downwards.

13. The apparatus of claim 12,
wherein the bottom cover is made from a single crystal or polycrystalline semiconductor of the same material as the semiconductor.

14. The apparatus of claim 13,
wherein the semiconductor is silicon or germanium.

15. The apparatus of claim 12,
wherein the body and the bottom cover are made from a quartz glass.

16. The apparatus of claim 12,
wherein the connection means is formed of a support wire or bar made from high melting point metals including molybdenum and tungsten, or an alloy thereof.

17. An apparatus for supplying a solid raw material to a crucible of a semiconductor single crystal grower, the solid raw material being a raw material of a semiconductor single crystal, the apparatus including:
a cylindrical body located above the crucible and detachably installed in the grower for receiving the solid raw material therein;
a bottom cover detachably installed in the bottom of the body for preventing the fall of the solid raw material and basically formed in the shape of a cone having an apex facing the solid raw material; and
a connection means connected in the vicinity of the apex of the conic bottom cover through the middle of an inner space of the body for relatively moving the bottom cover upwards and downwards with regard to the body,
wherein at least one concave portion or convex portion is formed on a conic surface of the bottom cover facing the solid raw material.

18. The apparatus of claim 17,
wherein at least one pair of concave portions or convex portions are formed on the conic surface of the bottom cover.

19. The apparatus of claim 18,
wherein a plurality of pairs of the concave portions or convex portions are alternately arranged along the circumference of the conic surface.

20. The apparatus of claim 17,
wherein the bottom cover is made from a single crystal or polycrystalline semiconductor of the same material as the semiconductor.

21. The apparatus of claim 20,
wherein the semiconductor is silicon or germanium.

22. The apparatus of claim 17,
wherein the body and the bottom cover are made from a quartz glass.

23. The apparatus of claim 17,
wherein the connection means is formed of a support wire or bar made from high melting point metals including molybdenum and tungsten, or an alloy thereof.

24. A method for supplying a solid raw material to a crucible containing a melt for semiconductor single crystal growth at a predetermined height, the solid raw material being a raw material of a semiconductor single crystal, the method comprising:
loading the solid raw material in a cylindrical body of a solid raw material supply apparatus while a bottom cover having the basic shape of a cone closes an opening of the body such that an apex of the cone of the bottom cover is located in an inner space of the body;
mounting the cylindrical body of the supply apparatus above the crucible such that the bottom cover faces the melt in the crucible; and
relatively moving the body and the bottom cover while the bottom cover is spaced away from the melt in the crucible at a predetermined distance to open the opening of the body, thereby charging the crucible with the solid raw material,
wherein the bottom cover is made from a single crystal or polycrystalline semiconductor of the same material as the semiconductor.

25. The method of claim 24,
wherein the semiconductor is silicon or germanium.

26. The method of claim 24,
wherein charging the crucible with the solid raw material includes relatively rotating the crucible and the body of the supply apparatus at a speed of 0.1 to 3 rpm.

27. The method of claim 24,
wherein the solid raw material is a polycrystalline semiconductor in the shape of a granule or a chip having a particle diameter of 3 to 30 mm.

28. The method of claim 24,
wherein a plurality of grooves are formed in the shape of a spiral on the conic surface of the cover facing the solid raw material from the apex of the bottom cover downwards, and
charging the crucible with the solid raw material includes charging the solid raw material in the crucible with a spiral trace.

29. The method of claim 24,
wherein at least one concave portion or convex portion is formed on the conic surface of the cover facing the solid raw material, and
in the step of charging the crucible with the solid raw material, a horizontal distance of the solid raw material falling along the concave portion or convex portion is different from the horizontal distance of the solid raw material falling along portions other than the concave portion or convex portion.
